(19) United States
(12) Patent Application Publication
(10) Pub. No.: US 2025/0329552 A1
(43) Pub. Date: Oct. 23, 2025

(54) SUBSTRATE CLEANING APPARATUS

(71) Applicant: Samsung Electronics Co., Ltd., Suwon-si (KR)

(72) Inventors: Inhyeong LEE, Suwon-si (KR); Donghoon KWON, Suwon-si (KR)

(21) Appl. No.: 19/019,762

(22) Filed: Jan. 14, 2025

(30) Foreign Application Priority Data
Apr. 23, 2024 (KR) 10-2024-0054291

(51) Int. Cl. H01L 21/67; A46B 13/00; A46B 13/04

(52) U.S. Cl. CPC H01L 21/67046; A46B 13/003; A46B 13/04; A46B 2200/3073

(57) ABSTRACT

A substrate cleaning apparatus includes a core including a plurality of segments having magnetism and one or more connectors connecting the plurality of segments to each other, the core being configured to rotate about a rotation axis; a brush surrounding at least a portion of the core and configured to rotate together with the core; and an adjustment frame spaced apart from an outer circumferential surface of the brush, the adjustment frame being configured to generate magnetic force to move at least one of the plurality of segments in a direction intersecting with the rotation axis.

### CROSS-REFERENCE TO RELATED APPLICATION

This application claims the benefit of Korean Patent Application No. 10-2024-0054291, filed on Apr. 23, 2024, in the Korean Intellectual Property Office, the disclosure of which is incorporated herein by reference.

### BACKGROUND

### 1. Field of the Invention

Example embodiments relate to a substrate cleaning apparatus.

### 2. Description of the Related Art

After a chemical mechanical polishing (CMP) process is performed for a wafer (substrate), a cleaning process may be performed to remove particles such as residues or organic pollutants generated on the surface of the wafer.

The cleaning process may be conducted such that a wafer enters between roll brushes disposed above and below the wafer and which rotate in place, and meanwhile, a cleaning solution is sprayed on the wafer and simultaneously the roll brushes are driven to rotate in a state of touching the wafer to clean the wafer's surface.

In existing cases, roll brushes may form a higher contact rate in the middle area of the wafer than at the edge of the wafer, and accordingly, the brush pressure is concentrated on the middle area of the wafer, which may cause the wafer damage or deterioration. In addition, as porous roll brushes hold a cleaning solution, sagging occurs in the middle portion of the roll brush, which causes the brush pressure to be further concentrated on the middle area of the wafer.

### SUMMARY

Aspects of the invention provide a substrate cleaning apparatus in order for a brush to apply uniform contact pressure to a substrate.

Aspects of the invention also provide a substrate cleaning apparatus for adjusting a position of each part of a brush individually.

Aspects of the invention also provide a substrate cleaning apparatus for enhancing the accuracy and efficiency of substrate cleaning.

The present disclosure is not limited to the aforementioned technical features, and other unstated technical features may be clearly understood by those skilled in the art from the descriptions below.

According to an aspect of the invention, a substrate cleaning apparatus includes a core including a plurality of segments having magnetism and one or more connectors connecting the plurality of segments to each other, the core being configured to rotate about a rotation axis; a brush surrounding at least a portion of the core and configured to rotate together with the core; and an adjustment frame spaced apart from an outer circumferential surface of the brush, the adjustment frame being configured to generate magnetic force to move at least one of the plurality of segments in a direction intersecting with the rotation axis.

According to another aspect of the invention, a substrate cleaning apparatus includes a core including a plurality of segments, the plurality of segments being configured to spray a cleaning liquid for cleaning a semiconductor substrate, and one or more connectors connecting the plurality of segments to each other; and a brush surrounding at least a portion of the core and configured to rotate together with the core as the core rotates about a rotation axis, wherein at least one segment among the plurality of segments is configured to move in a direction intersecting the rotation axis with respect to another segment, and wherein a connector of the one or more connectors that is connected to the at least one segment is configured to change shape with movement of the at least one segment.

According to another aspect of the invention, a substrate cleaning apparatus includes a core including: a plurality of segments provided with spray holes for spraying a cleaning liquid, and one or more connectors having a different structure from the plurality of segments, wherein the core is rotatable centering on a rotation axis, wherein the plurality of segments and one or more connectors are alternately arranged in a direction parallel to the rotation axis; a brush surrounding at least a portion of the plurality of segments and configured to clean a substrate; and an adjustment frame configured to adjust a distance between at least one of the plurality of segments and the substrate.

According to another aspect of the invention, a substrate cleaning apparatus includes a core including a plurality of segments arranged in a longitudinal direction of the core, the core being configured to rotate about a rotational axis; a brush surrounding at least a portion of the core and configured to rotate together with the core; and a controller configured to rotate the core and configured to move at least one of the plurality of segments in a radial direction of the core.

Details of example embodiments are included in the detailed description and drawings.

According to the example embodiments of the present disclosure, it is possible to implement a substrate cleaning apparatus for applying uniform contact pressure to a substrate using a segmented-type brush assembly.

In addition, according to the example embodiments of the present disclosure, it is possible to provide a substrate cleaning apparatus for adjusting a position of each part of a segmented-type brush assembly individually.

In addition, according to the example embodiments of the present disclosure, it is possible to increase the accuracy and efficiency of substrate cleaning using a segmented-type brush assembly for adjusting a position of each part individually.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a perspective view of a substrate cleaning apparatus according to example embodiments;

FIG. 2 is a bottom view of a substrate cleaning apparatus according to example embodiments;

FIG. 3 is a reference diagram for illustrating configurations of a substrate cleaning apparatus according to example embodiments;

FIG. 4 is an illustrative exploded perspective view of a brush assembly included in a substrate cleaning apparatus according to example embodiments;

FIG. 5 is an enlarged partial view of a brush assembly according to an example embodiment;

FIG. 6 is an enlarged partial view of a brush assembly according to another example embodiment;

FIG. 7A shows an illustrative cross-sectional view of a brush assembly according to example embodiments;

FIG. 7B shows an illustrative cross-sectional view of a brush assembly according to example embodiments;

FIG. 7C shows an illustrative cross-sectional view of a brush assembly according to example embodiments;

FIG. 8 is a reference diagram for illustrating an operation of a brush assembly according to an example embodiment;

FIG. 9 is a reference diagram for illustrating an operation of a brush assembly according to an example embodiment;

FIG. 10 is a reference diagram for illustrating configurations of a brush assembly according to another example embodiment;

FIG. 11 is a reference diagram for illustrating configurations of a brush assembly according to another example embodiment;

FIG. 12 is a reference diagram for illustrating configurations of a brush assembly according to another example embodiment; and

FIG. 13 is a reference diagram for illustrating a substrate processing apparatus including a substrate cleaning apparatus according to example embodiments.

### DETAILED DESCRIPTION

Before describing example embodiments in detail, the words and terminologies used in the specification and claims are not to be construed as limited to common or dictionary meanings but construed as meanings and conceptions coinciding with the technical spirit of the present disclosure under a principle that the inventor(s) may appropriately define the conception of the terminologies to explain the invention in the optimum manner. Therefore, the example embodiments described in the specification and the configurations illustrated in the drawings are not more than the most preferred example embodiments of the present disclosure and do not fully cover the spirit of the present disclosure. Accordingly, it should be understood that there may be various equivalents and modifications that may replace those when this application is filed.

In the descriptions below, a singular expression includes a plural expression unless contextually apparently otherwise defined. It should be understood that terms such as “comprise or include” or “consist of” specify the presence of a characteristic, a number, a step, an operation, an element, a component, or a combination thereof which are described in the specification and do not previously exclude the possibility of the presence or addition of one or more other characteristics, numbers, steps, operations, elements, components, or combinations thereof.

Further, in the descriptions below, expressions such as upper side, upper portion, lower side, lower portion, side surface, front surface, back surface, and the like are represented based on directions illustrated in the drawings and may be otherwise represented when the direction of the corresponding object changes. The shapes and sizes of elements in the drawings may be exaggerated for clear descriptions.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Hereinafter, a substrate cleaning apparatus according to example embodiments is explained with reference to the attached drawings.

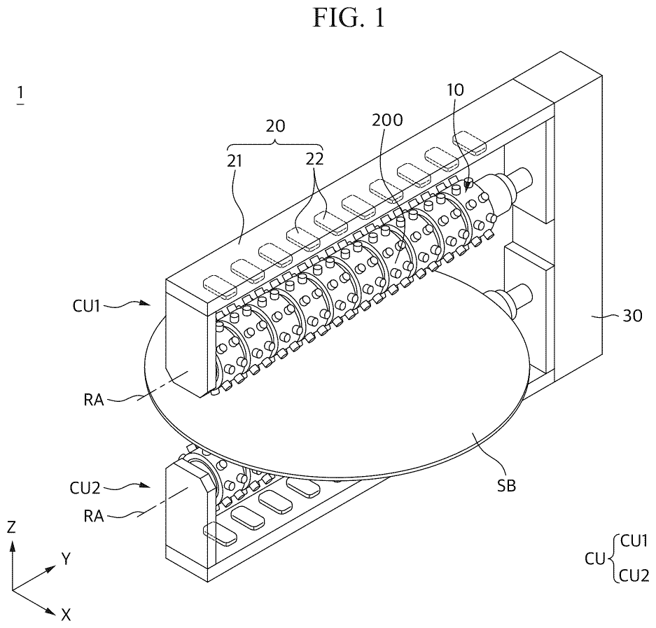

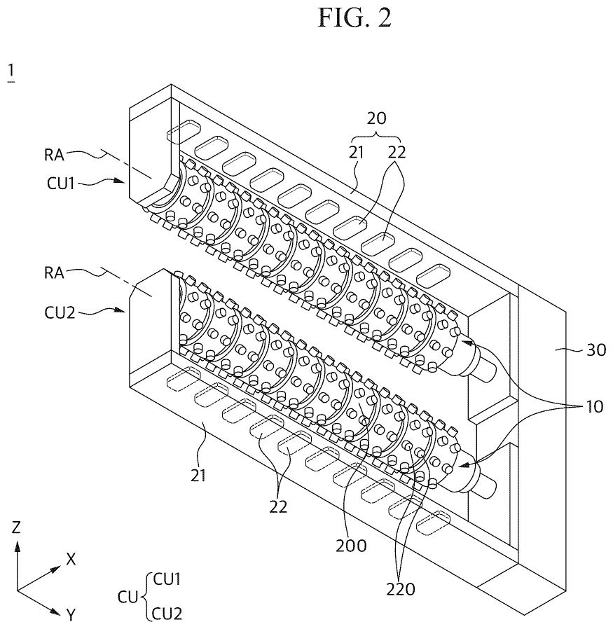

FIG. 1 is a perspective view of a substrate cleaning apparatus 1 according to example embodiments. FIG. 2 is a bottom view of the substrate cleaning apparatus 1 according to example embodiments.

The substrate cleaning apparatus 1 according to example embodiments may be configured to perform a cleaning process of removing particles such as slurry or organic pollutants present on the surface of a wafer (substrate) in a semiconductor manufacturing process.

Referring to FIGS. 1 and 2, the substrate cleaning apparatus 1 may include one or more cleaning units CU equipped with a brush 200 and a support frame 30 supporting the cleaning units CU.

In example embodiments, the cleaning units CU may include a brush assembly 10 cleaning a substrate SB and a position adjustment part 20 (e.g., an adjustment frame) disposed at one side of the brush assembly 10.

The brush assembly 10 sprays a cleaning liquid to the substrate SB, and simultaneously, the brush 200 may rotate clockwise or counterclockwise centering on a rotation axis RA in a state of contacting a surface of the substrate SB to clean the substrate SB. Here, as the cleaning liquid, anything generally used for cleaning a semiconductor substrate may be applied without limitation.

In example embodiments, the brush 200 of the brush assembly 10 may include materials that may provide friction force enough to hold the sprayed cleaning liquid and wipe particles on the surface of the substrate SB at the same time. For example, the brush 200 may include various resin materials in a porous form, including polyvinyl acetate (PVA). To enhance a cleaning capability, a plurality of cleaning protrusions 220 may be provided at an outer circumferential surface of the brush 200.

In example embodiments, the substrate cleaning apparatus 1 may be configured to clean different surfaces of the substrate SB by including a plurality of cleaning units CU. For example, as shown in FIGS. 1 and 2, the substrate cleaning apparatus 1 may include a first cleaning unit CU1 and a second cleaning unit CU2 which are disposed above and below the substrate SB to clean upper and lower surfaces of the substrate SB. The brush assembly 10 of the first cleaning unit CU1 and the brush assembly 10 of the second cleaning unit CU2 may be disposed to be spaced apart from each other by a predetermined distance, and with the substrate SB positioned in between, the brush assemblies 10 of each of the cleaning units CU1, CU2 may be driven to rotate and spray cleaning liquids to clean opposite surfaces of the substrate SB. Though not illustrated in the drawings, the substrate cleaning apparatus 1 may further include a substrate rotating part (not shown) such as, e.g., a motor and/or an actuator controlled by a controller, configured to rotate the substrate SB centering on a vertical axis (for example, an axis parallel with a z-axis) in a cleaning process.

In example embodiments, the substrate cleaning apparatus 1 may further include the support frame 30 supporting the first cleaning unit CUI and the second cleaning unit CU2. In order to respond to the size (for example, thickness) of the substrate SB, the first cleaning unit CU1 and the second cleaning unit CU2 may be configured to be movable in a direction closer to each other or farther therefrom on the support frame 30. Therefore, a user may effectively clean an upper surface and a lower surface of the substrate SB by adjusting a distance between the first cleaning unit CU1 and the second cleaning unit CU2 in response to various sizes of substrates. However, unlike illustrations in the drawings, in example embodiments, the substrate cleaning apparatus 1 may have one or more than two cleaning units CU, and a disposition of the cleaning units CU may also be appropriately changed in response to the shape of the substrate SB.

For example, the first cleaning unit CU1 and the second cleaning unit CU2 may be moved by a motor and/or an actuator that is controlled, e.g., by a controller. Although not illustrated, a controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

In example embodiments, in a process of cleaning the substrate SB using the brush assembly 10, the substrate cleaning apparatus 1 may further include the position adjustment part 20 which may adjust the position of each part of the brush assembly 10 relative to the substrate SB so as to adjust for each area of the brush assembly 10 the amount of pressure (hereinafter, referred to as contact pressure) which is applied as the brush 200 of the brush assembly 10 is contacted to the substrate SB, the area (hereinafter, referred to as contact area) in which the brush 200 contacts the substrate SB, or the friction force (hereinafter, referred to as contact friction force) which is generated by contact.

In example embodiments, the position adjustment part 20 may be configured to adjust the position of at least a portion of the brush assembly 10. For example, the brush assembly 10 may be configured to be segmented along a longitudinal direction (y-axis direction) so that each part thereof is movable relative to and independently from another part, and the position adjustment part 20 may be configured to adjust a position of each part (hereinafter, referred to as “segmented part”) segmented in the brush assembly 10 individually. The position adjustment part 20 may be controlled, for example, by a controller as described above.

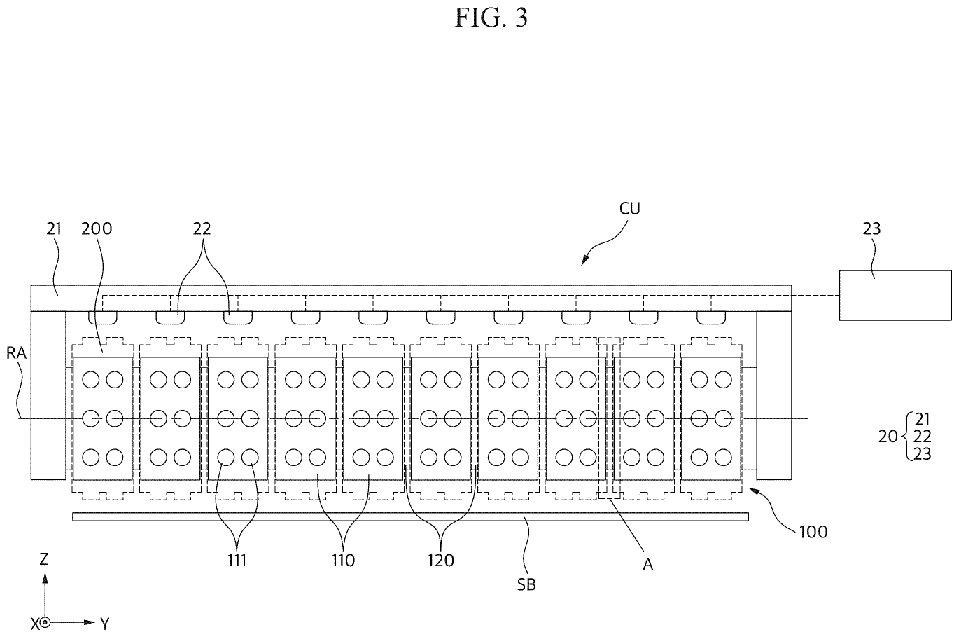

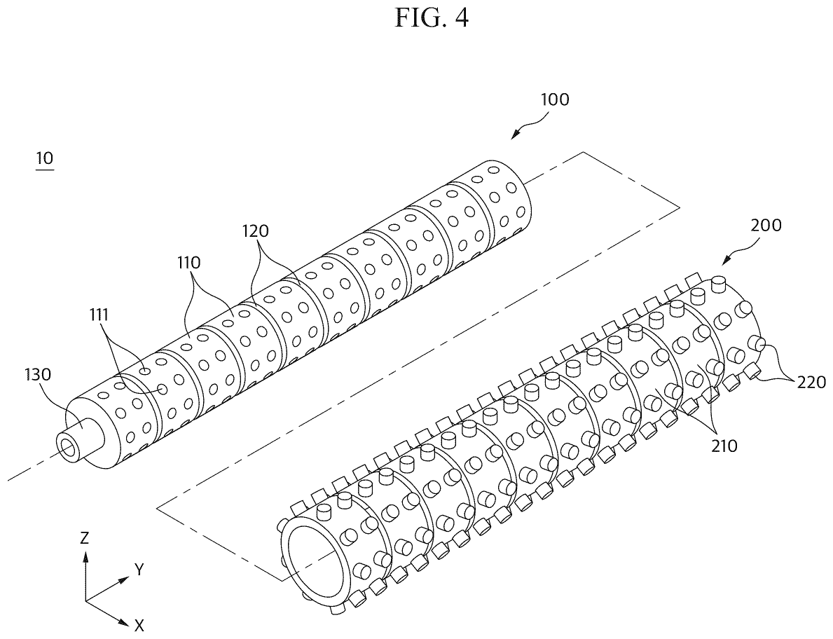

In example embodiments, the position adjustment part 20 may adjust the position of each part (in other words, each segmented part) segmented in the brush assembly 10 using magnetic force. For example, at least some of the segmented parts of the brush assembly 10 may include a material having magnetism, and the position adjustment part 20 may include a magnetic object 22, in which magnetic force is generated, to push or pull a part having magnetism in the brush assembly 10 through the magnetic force of the magnetic object 22 to adjust positions of segmented parts individually. A segmented structure of the brush assembly 10 is described later with reference to FIGS. 3 and 4.

Referring back to FIGS. 1 and 2, the position adjustment part 20 may include a holder 21 disposed at one side of the brush assembly 10 and one or more magnetic objects 22 fixed on the holder 21.

In example embodiments, the magnetic object 22 of the position adjustment part 20 may be disposed at a surface of the holder 21 facing the brush assembly 10. For example, as in FIGS. 1 and 2, a plurality of the magnetic objects 22 of the position adjustment part 20 may be disposed at the surface facing the brush assembly 10 on the holder 21. The plurality of magnetic objects 22 may be arranged in a direction parallel with the rotation axis RA.

In example embodiments, the holder 21 may be configured to be movable relative to the brush assembly 10. A user may adjust a distance between the magnetic object 22 and the brush assembly 10 by appropriately adjusting the position of the holder 21.

In example embodiments, a plurality of magnetic objects 22 of the position adjustment part 20 may include electromagnets in which magnetic force is generated when power is applied. In this case, as power is applied to any one of the plurality of electromagnets, magnetic force is generated and a segmented part positioned closest to the electromagnet to which power is applied is pulled, which accordingly may move the position of the corresponding segmented part.

Thus, the position adjustment part 20 according to example embodiments, by adjusting the position of each part of the brush assembly 10 individually, may control to individually adjust contact pressure which each part of the brush 200 applies to the substrate SB in a process of cleaning the substrate SB by the brush assembly 10.

Through the position adjustment part 20, the substrate cleaning apparatus 1 according to example embodiments may have the contact pressure applied by the brush 200 formed evenly throughout entire area of the substrate SB in a substrate cleaning process. In other words, when a specific area of the brush assembly 10 cleans the substrate SB using a stronger contact pressure than another area, the substrate cleaning apparatus 1 can adjust the position of a segmented part corresponding to the specific area through the position adjustment part 20, ensuring that the entire area of the brush assembly 10 applies uniform contact pressure to the substrate SB. Accordingly, a cleaning process may be improved by preventing a specific area of the substrate SB from being intensively cleaned under a relatively strong contact pressure.

In addition, the contact area and the contact pressure in which the brush assembly 10 contacts a specific area of the substrate SB may be finely adjusted by a user-desired amount through the position adjustment part 20 in example embodiments. Accordingly, the substrate SB may be cleaned in different intensities for each area, which thus may maximize the cleaning capability of the substrate cleaning apparatus 1 and may reduce the failure rates of wafers.

Hereinafter, with reference to FIGS. 3 to 7, the brush assembly 10 and the position adjustment part 20 are described further in detail.

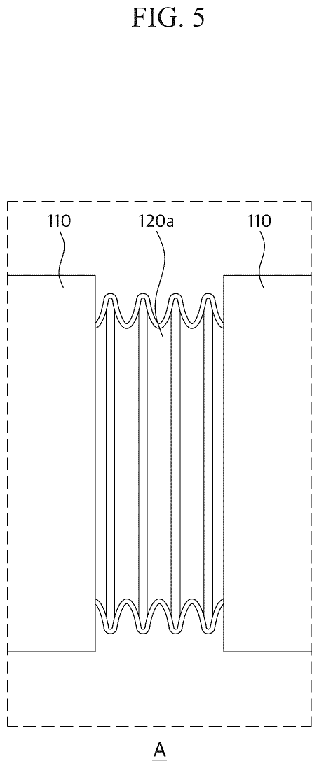

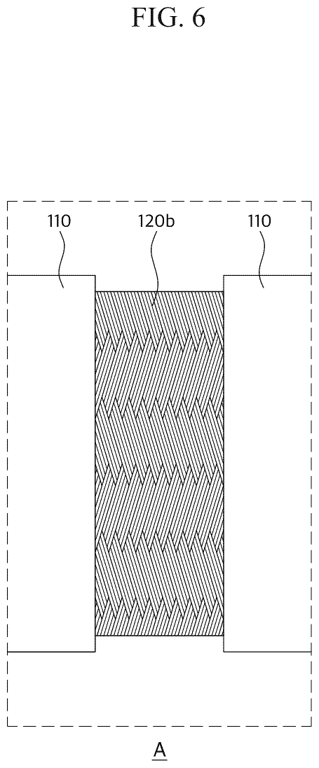

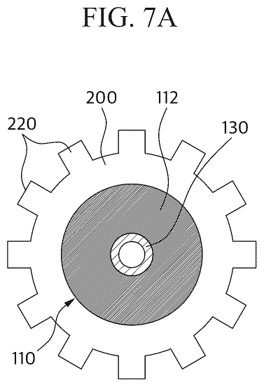

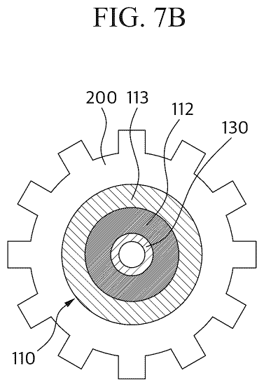

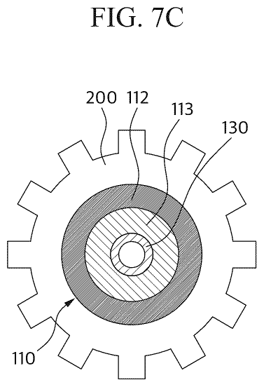

FIG. 3 is a reference diagram for illustrating configurations of a substrate cleaning apparatus according to example embodiments. FIG. 4 is an illustrative exploded perspective view of the brush assembly 10 included in a substrate cleaning apparatus according to example embodiments. FIG. 5 is an enlarged partial view of the brush assembly 10 according to an example embodiment. FIG. 6 is an enlarged partial view of the brush assembly 10 according to another example embodiment. FIG. 7A is an illustrative cross-sectional view of the brush assembly 10 according to example embodiments. FIG. 7B is an illustrative cross-sectional view of the brush assembly 10 according to example embodiments. FIG. 7C is an illustrative cross-sectional view of the brush assembly 10 according to example embodiments.

A substrate cleaning apparatus described in FIGS. 3 to 7C corresponds to the substrate cleaning apparatus 1 described above through FIGS. 1 and 2, and duplicate descriptions may be omitted.

In example embodiments, a substrate cleaning apparatus (for example, 1 of FIGS. 1 and 2) includes one or more cleaning units CU which may clean the surface of the substrate SB, and each cleaning unit CU may include the brush assembly 10 which cleans the substrate SB and the position adjustment part 20 which may adjust the position of each area of the brush assembly 10.

In example embodiments, the brush assembly 10 has a structure segmented along the longitudinal direction (for example, y-axis direction) thereof and may be configured for each segmented part to be movable relative to another part. For example, referring to FIGS. 3 and 4, the brush assembly 10 may include a core assembly 100 (e.g., a core) which has a segmented-type structure and is rotatable centering on the rotation axis RA and the brush 200 which covers at least part of a surface of the core assembly 100 and rotates together with the core assembly 100.

In example embodiments, the core assembly 100 includes a plurality of body parts 110 (e.g., segments) where a spray hole 111, through which a cleaning liquid is sprayed, is provided and a connection part 120 (e.g., a connector) which connects the plurality of body parts 110 and has a flexible structure, and each body part 110 may be configured to be movable relative to another body part 110 in a predetermined range. For example, each body part 110 may include one or more spray holes 111. In some embodiments, some of the body parts 110 may include one or more spray holes 111 and some other body parts 110 may not include any spray holes 111.

In example embodiments, a flow path part 130 (e.g., a conduit or channel) through which a cleaning liquid may flow may be disposed inside the core assembly 100. The flow path part 130 may be provided as a pipe-type member (e.g., a pipe) that penetrates the multiple body parts 110 and the connection part 120 in the longitudinal direction (for example, y-axis direction) of the core assembly 100.

In example embodiments, the cleaning liquid flowing along the flow path part 130 may be sprayed through the spray hole 111 communicating with the flow path part 130 to an outer side of the core assembly 100. The brush 200 of an outer surface of the core assembly 100 may clean the substrate SB rotating with the sprayed cleaning liquid held.

In example embodiments, the connection part 120 may connect the plurality of body parts 110 to each other. Referring to FIGS. 3 and 4, the plurality of body parts 110 are disposed along (e.g., arranged in) the longitudinal direction (y-axis direction) of the core assembly 100, between which the connection part 120 having flexibility is positioned and may connect the body parts 110 flexibly. In other words, the core assembly 100 may have a segmented-type structure in which the body part 110 and the connection part 120 are alternately repeated in the longitudinal direction (y-axis direction). In the segmented-type structure above, as any one body part 110 moves in a direction (for example, a direction intersecting the rotation axis RA) relative to another body part 110, the connection part 120 connected to one side or both sides of the moving body part 110 may be transformed in shape.

In example embodiments, the connection part 120 may have a transformable (e.g., deformable) structure or a transformable material in response to the movement of the body parts 110. For example, referring to FIG. 5, the connection part 120 may have a structure of a corrugated pipe 120a which may flexibly connect the plurality of body parts 110 to each other. The structure of the corrugated pipe 120a above is flexibly transformable not only up and down and right and left but also in a longitudinal direction, which thus may not interrupt the movement of the body parts 110.

Alternatively, as in FIG. 6, the connection part 120 may have a pipe-type structure (hereinafter, braided wire structure) consisting of a plurality of wires braided. Each wire forming a braided wire structure 120b may be composed of a metal material. In this case, to minimize the influence of a magnetic field generated from the magnetic object 22, the material of the wire may include a metal without magnetism. However, the braided wire structure 120b may also include a wire that is magnetic, but that is not magnetic enough to influence the movement of the body parts 110. The braided wire structure 120b above may stably connect the plurality of body parts 110 and also secure great flexibility of the connection part 120.

Alternatively, unlike FIGS. 5 and 6, the connection part 120 may have a simple pipe-type structure but has predetermined flexibility and may consist of a synthetic resin material that is transformable in response to the movement of the body parts 110. However, a structure or a material of the connection part 120 is not limited to the descriptions above, and any structure or material stably connecting the plurality of body parts 110 and transformable in response to the movement of the body parts 110 may be applied without limitation.

In example embodiments, the brush 200 covering the core assembly 100 may also have a segmented structure to correspond to each of the plurality of body parts 110. For example, referring to FIGS. 3 and 4, the brush 200 may consist of a plurality of sub-brushes 210 segmented to be movable relative to each other. Each of the sub-brushes 210 may be provided as a separate member that is completely separated from each other sub-brush 210. However, the structure of the brush 200 is not limited thereto. For example, the sub-brushes 210 may be connected to each other through members flexible enough not to interrupt the movement of the body parts 110. Alternatively, when the brush 200 itself consists of a material flexible enough not to interrupt the movement of the body parts 110, the brush 200 may be provided without a segmented structure.

In example embodiments, at least one of the plurality of body parts 110 of the core assembly 100 may have magnetism. FIG. 7A to 7C may show various cross-sectional structures of the body parts 110 having magnetism above.

Referring to FIG. 7A, the body part 110 surrounded with the brush 200 having the cleaning protrusions 220 may include a magnetic part 112 (e.g., a magnetic material) including a material having magnetism enough to be movable by magnetic force generated by the position adjustment part 20.

In example embodiments, the magnetic part 112 of the body part 110 may include a magnetic polymer (or organic magnet) substance. For example, the magnetic polymer may include PANiCNQ polymer which is a combination of emeraldine-based polyaniline (PANi) and tetracyanoquinodimethane (TCNQ).

In example embodiments, the magnetic part 112 may also include a material in which a polymer substance without magnetism (or having very weak magnetism) such as polyurethane or polyamide is mixed with a magnetic particle having strong magnetism. For example, the magnetic particle may be a metal particle including any one or more selected from a group having iron (Fe), chromium (Cr), nickel (Ni), cobalt (Co), and manganese (Mn). For example, the magnetic particle may include ferromagnetic particles such as Fe₂O₃, CoFe₂O₄, FeOFe₂O₃, NiOFe₂O₃, CuOFe₂O₃, MgOFe₂O₃, MnBi, MnSb, MnOFe₂O₃, Y₃Fe₅O₁₂, CrO₂, MnAs, and EuO. Alternatively, the magnetic part 112 may consist of a material in which a magnetic polymer substance is mixed with a magnetic particle.

The magnetic part 112 above has strong magnetism and may react to a magnetic field generated in the position adjustment part 20, although positioned inside the brush 200.

Referring to FIG. 7B, in another example embodiment, the body part 110 may also be formed in a multi-layer structure in which a non-magnetic part 113 (e.g., a non-magnetic material) without magnetism (or having very weak magnetism) covers an outer circumferential surface of the magnetic part 112. Here, the magnetic part 112 may have characteristics of the magnetic part 112 which are described above. The non-magnetic part 113 may include an engineering plastic material generally used such as polyetheretherketone (PEEK). As a portion of the body part 110 is composed of the engineering plastic material thus, the core assembly 100 may be implemented, which has the magnetic part 112 and at the same time has superior chemical resistance, wear resistance, thermal resistance, water resistance, and processability, characteristics of the engineering plastic material.

Alternatively, referring to FIG. 7C, the body part 110 may also have a structure in which the magnetic part 112 covers the non-magnetic part 113. In this case, the magnetic part 112 is positioned further outwards and thus is closer to the position adjustment part 20, which may make it easier to adjust the position of the body part 110 by magnetic force.

In example embodiments, the position adjustment part 20 may adjust the position of each part of the brush assembly 10 by individually adjusting the positions of the plurality of body parts 110 using magnetic force generated from the magnetic object 22.

The magnetic object 22 of the position adjustment part 20 includes electromagnets and may move the body parts 110 positioned closest thereto as power is applied and magnetic force is generated. For example, the magnetic object 22 may include a solenoid electromagnet (or a coil electromagnet).

The substrate cleaning apparatus 1 may further include a controller 23 that may control whether the magnetic force of each magnetic object 22 including electromagnets is generated and the strength of the magnetic force. The controller 23 may control a current applied to each magnetic object 22 to control the magnetic force of the magnetic object 22.

In example embodiments, the position adjustment part 20 may adjust a distance between the brush assembly 10 and the substrate SB by individually adjusting the positions of the plurality of body parts 110.

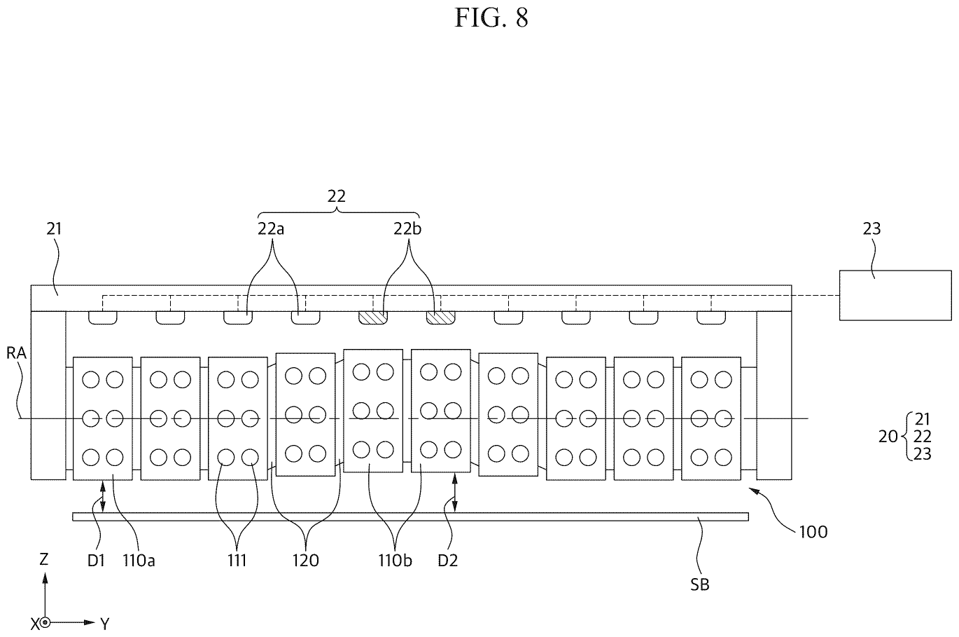

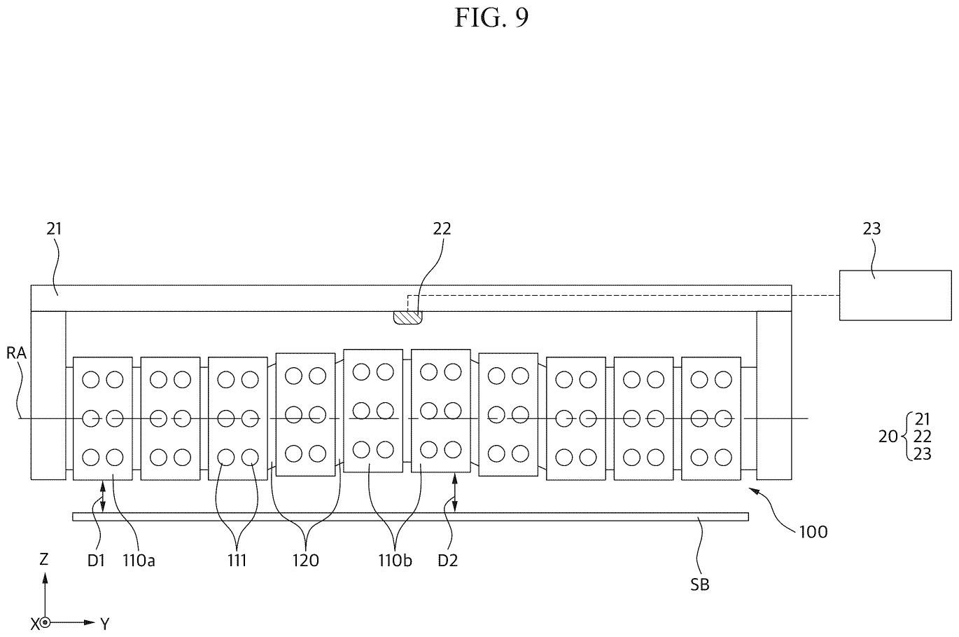

Hereinafter, referring to FIGS. 8 and 9 together, operations of the brush assembly 10 by the position adjustment part 20 in various example embodiments are described further in detail.

FIG. 8 is a reference diagram for illustrating an operation of a brush assembly according to an example embodiment. FIG. 9 is a reference diagram for illustrating an operation of a brush assembly according to an example embodiment.

A substrate cleaning apparatus described in FIGS. 8 and 9 corresponds to the substrate cleaning apparatus 1 described above through FIGS. 1 to 7, and duplicate descriptions may be omitted.

Referring to FIGS. 3, 8, and 9 together, the position adjustment part 20 may include the holder 21 disposed at an opposite side to a side facing a substrate in the brush assembly 10 and one or more magnetic objects 22 supported by the holder 21 and disposed to face the brush assembly 10 in the vertical direction in example embodiments. According to such a structure, when a current is applied to the magnetic object 22 and magnetic force is generated, the body part 110 positioned closest thereto and the brush 200 covering the body part moves closer to the magnetic object 22 in the vertical direction by magnetic attraction, and accordingly, a distance between a body part 110 corresponding to the magnetic object 22 to which a current is applied in the brush assembly 10 and the substrate SB may increase.

For example, referring to FIG. 8, as currents are applied to some magnetic objects 22b positioned in the middle among the plurality of magnetic objects 22 disposed in a direction parallel with the rotation axis RA, magnetic force may be generated. Accordingly, body parts 110b facing the magnetic objects 22b (hereinafter, referred to as operating magnetic objects) to which the currents are applied move in a direction toward the operating magnetic objects 22b, and a distance between the corresponding body parts 110b and the substrate SB may increase. In this case, in response to the movement of the body parts 110b, the connection part 120 adjacent thereto is transformed and the body parts 110b may move without much resistance.

Meanwhile, since no magnetic force is generated from magnetic objects 22a (hereinafter, referred to as non-operating magnetic objects) to which currents are not applied, body parts 110a facing the non-operating magnetic objects 22a may maintain a distance to the substrate SB unless other external forces are present.

Accordingly, a distance D2 between the body parts 110b of a middle portion positioned relatively close to the operating magnetic objects 22b and the substrate SB may be greater than a distance D1 between the body parts 110a of edges positioned relatively far from the operating magnetic objects 22b and the substrate SB.

While the brush assembly 10 is driven as rotating centering on the rotation axis RA and cleans a substrate, the position adjustment part 20 may stay in an operating state, and accordingly, the body parts 110b positioned relatively close to the operating magnetic objects 22b may rotate while maintaining a distance to the substrate SB to be greater than the body parts 110a positioned relatively far from the operating magnetic objects 22b.

According to such position adjustment of the body parts 110, while the brush assembly 10 cleans the substrate SB, the contact pressure or the contact area of a middle portion of the brush assembly 10 may be reduced. In particular, according to such position adjustment of the body parts 110, it may be prevented that the brush 200 holding a cleaning liquid, where the middle of the brush 200 sags down by the load thereof compared to edges, applies relatively high contact pressure to a specific area of the substrate SB. In other words, the body parts 110 corresponding to the middle portion of the brush 200, where sagging is a concern, are pulled up using the magnetic objects 22 of the position adjustment part 20, which may cause contact pressure to be formed uniformly throughout every area of the brush 200.

Meanwhile, referring to FIG. 9, only one magnetic object 22 of the position adjustment part 20 may be present, at a position corresponding to the middle of the longitudinal direction of the brush assembly 10. When a current is applied to the magnetic object 22 and the magnetic force is generated, the body parts 110b close to the magnetic object 22 are attracted to the magnetic object 22 by magnetic attraction, and accordingly, the distance D2 between the body parts 110b positioned in the middle of the brush assembly 10 and the substrate SB becomes greater than the distance D1 between the body part 110a at an edge and the substrate SB.

However, in addition to examples of the position adjustment illustrated in FIGS. 8 and 9, the position adjustment part 20 may be configured to adjust the position of each part of the brush assembly 10 individually.

For example, as illustrated in FIGS. 3 and 8, the magnetic objects 22 of the position adjustment part 20 are provided in the number corresponding to the number of the plurality of body parts 110 and may be disposed to be matched one to one with each of the body parts 110. In this case, each of the magnetic objects 22 may be disposed to face the corresponding body part 110 in the vertical direction. According to such a structure, all body parts 110 are positioned close to the magnetic objects 22, and thus, the position adjustment of each part including edges of the brush assembly 10 may be implemented rapidly and accurately, and the brush assembly 10 may be transformed to various shapes.

In example embodiments, the controller 23 may be configured to adjust the size of a current applied to each magnetic object 22, and accordingly, a user may adjust the size of magnetic force generated from each magnetic object 22 to adjust the contact pressure, contact area, or contact friction force of the brush assembly 10 based on a condition of a substrate processing process.

Thus, the substrate cleaning apparatus 1 according to example embodiments, by partially adjusting a distance between the brush assembly 10 and the substrate SB through the brush assembly 10 of a segmented structure having magnetism and the position adjustment part 20 in which magnetic force is generated, may make the strength of contact pressure or contact friction force which the brush assembly 10 applies to the substrate SB have user-desired distribution.

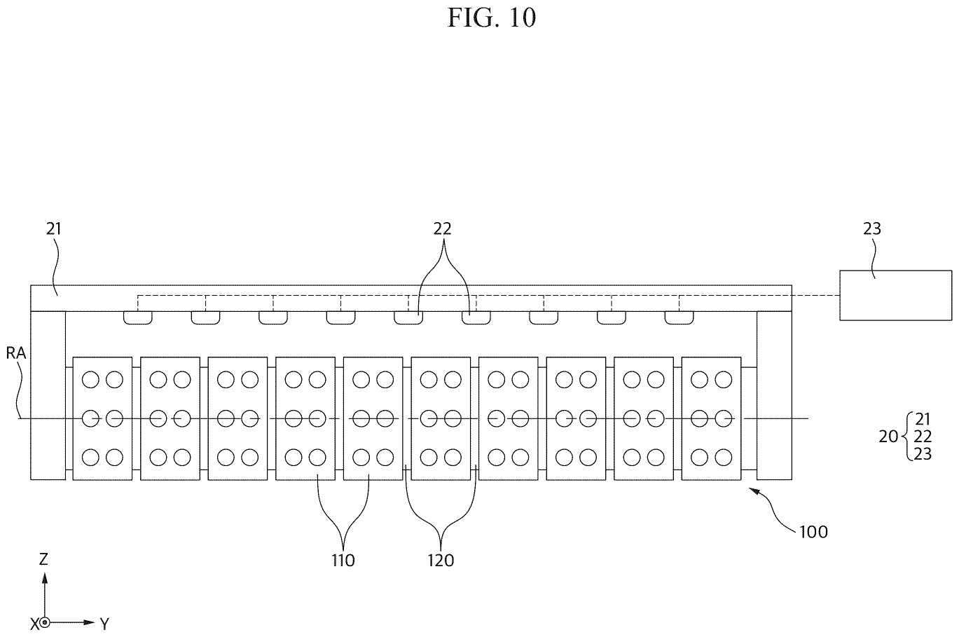

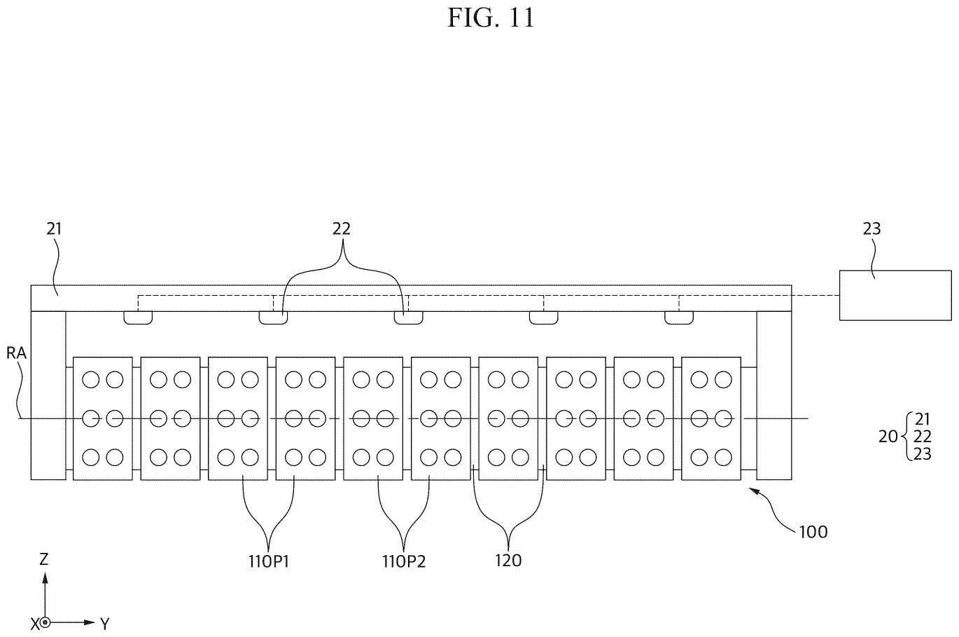

In another example embodiment, the magnetic objects 22 of the position adjustment part 20 may be positioned in various patterns. Hereinafter, with reference to FIGS. 10 and 11, a substrate cleaning apparatus according to another example embodiment is described.

FIG. 10 is a reference diagram for illustrating configurations of a brush assembly according to another example embodiment. FIG. 11 is a reference diagram for illustrating configurations of a brush assembly according to another example embodiment.

In a substrate cleaning apparatus described in FIGS. 10 and 11, other characteristics excluding a position where the magnetic object 22 is positioned are all identical to the substrate cleaning apparatus 1 described through FIGS. 1 to 9, and thus, descriptions duplicated with those of the above drawings may be omitted.

In example embodiments, the magnetic object 22 of the position adjustment part 20 may be positioned in various patterns.

For example, referring to FIG. 10, the number of the plurality of magnetic objects 22 may be less than the number of the plurality of body parts 110, and at least one magnetic object 22 is disposed to face the connection part 120 in the vertical direction. In this configuration, the magnetic force generated from one magnetic object 22 may influence two or more body parts 110 at an identical level. According to such a structure, since fewer magnetic objects 22 than body parts 110 are provided and simultaneously the positions of the multiple body parts 110 may be controlled individually, the efficiency of the position adjustment part 20 may be increased.

In addition, referring to FIG. 11, the plurality of magnetic objects 22 may be positioned so that each magnetic object 22 is matched to two body parts 110 in another example embodiment. In this case, at least one magnetic object 22 is disposed to face the connection part 120 in the vertical direction, which thus may have the magnetic force generated from one magnetic object 22 influence two or more body parts 110 at an identical level. Through such a structure, the positions of the multiple body parts 110 may be controlled using a quantity of the magnetic objects 22 that is less than that illustrated in FIG. 10. For example, a single magnetic object 22 may be used to control a pair of body parts 110 or a group of body parts 110.

Furthermore, according to example embodiments, the multiple magnetic objects 22 may be positioned concentrating on a position corresponding to a portion where more precise position control is required in the brush assembly 10, each magnetic object 22 may be formed differently in size, or a plurality of the magnetic objects 22 may be positioned to be matched to one body part 110.

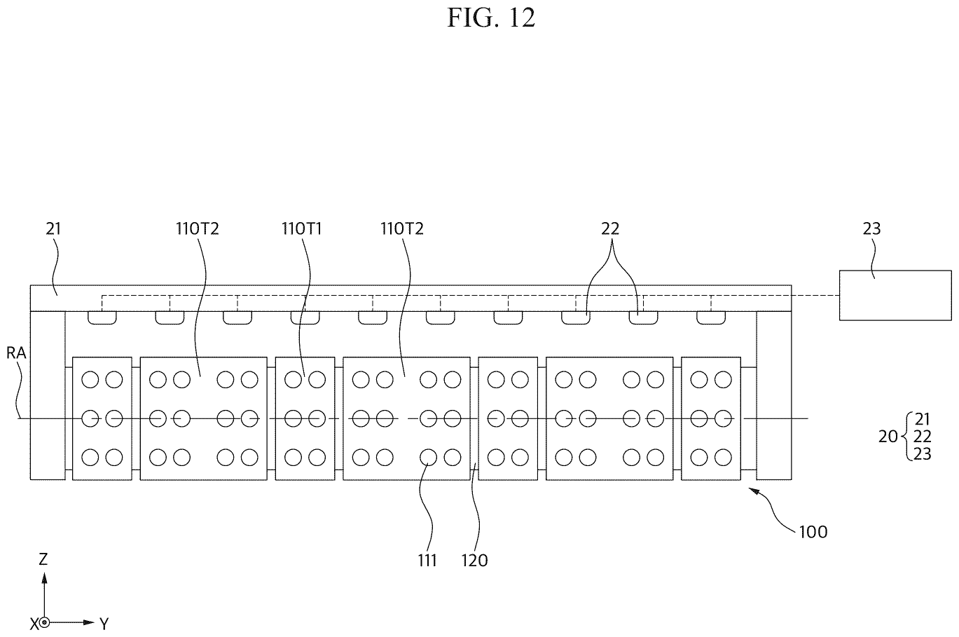

In another example embodiment, the brush assembly 10 may include a plurality of body parts having shapes different from each other. Hereinafter, with reference to FIG. 12, a substrate cleaning apparatus according to another example embodiment is described.

FIG. 12 is a reference diagram for illustrating configurations of a brush assembly according to another example embodiment.

In a substrate cleaning apparatus described in FIG. 12, other characteristics excluding the size of the body parts 110 are all identical to the substrate cleaning apparatus 1 described through FIGS. 1 to 9, and thus, descriptions duplicated with those of the above drawings may be omitted.

In example embodiments, the brush assembly 10 may include a plurality of body parts 110T1 and 110T2 having different sizes. For example, the brush assembly 10 may include N types of body parts having different lengths in a direction parallel with the rotation axis RA (here, N is a natural number greater than or equal to 2).

Referring to FIG. 12, the plurality of body parts 110T1 and 110T2 may include a first body part 110T1 that is relatively shorter in length in the direction parallel with the rotation axis RA and a second body part 110T2 that is relatively longer in length. According to such a configuration, the first body part 110T1 is positioned concentrating on a portion in which detailed position adjustment is required along the longitudinal direction (y-axis direction) in the brush assembly 10 and the second body part 110T2 is positioned in the other portion, which may achieve accuracy and efficiency of position adjustment in each area of the brush assembly 10 at the same time.

When the sizes of each of the body parts 110T1 and 110T2 change, the number of the magnetic objects 22 matched to each of the body parts 110T1 and 110T2 may vary in response thereto. For example, referring to FIG. 12, the first body part 110T1 may be configured to be matched to one magnetic object 22, and the second body part 110T2 which is longer may be configured to be matched to two or more magnetic objects 22. By matching more magnetic objects 22 to the relatively larger body part 110T2 thus, sufficient magnetic force may be applied to the corresponding body part 110T2.

Further, when the sizes of each of the body parts 110T1 and 110T2 change as in FIG. 12, the number of spray holes 111 provided in each of the body parts 110T1 and 110T2 may vary in response thereto.

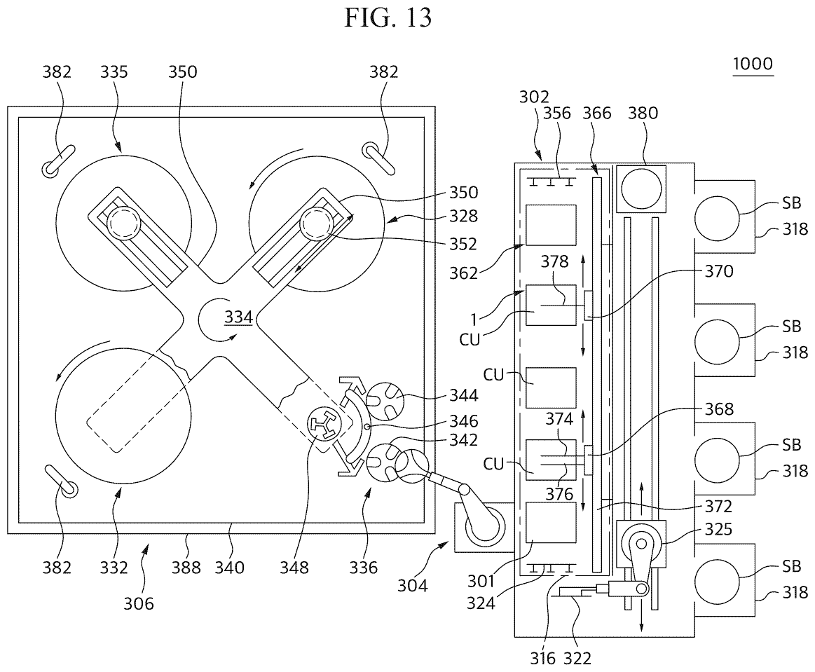

FIG. 13 is a reference diagram for illustrating a substrate processing apparatus including a substrate cleaning apparatus according to example embodiments.

Referring to FIG. 13, a substrate processing apparatus 1000 may include a polishing module 306 that polishes a surface of a substrate and the substrate cleaning apparatus 1 that cleans the substrate SB polished in the polishing module 306. The substrate processing apparatus 1000 may include a factory interface 302, a loading robot 304, and the polishing module 306.

In example embodiments, the factory interface 302 may include a cleaner 316, a plurality of substrate cassettes 318, an interface robot 325, and a measurement system 380. The cleaner 316 may include an input module 324, a plurality of substrate cleaning apparatuses 1, a drying module 362, a substrate handler 366 disposed on the substrate cleaning apparatus 1, and an output module 356. The input module 324 may serve as a transfer station between the factory interface 302, the cleaner 316, and the polishing module 306.

In example embodiments, the substrate cleaning apparatus 1 may include the cleaning unit CU described with reference to FIGS. 1 to 12. The number and disposition of the substrate cleaning apparatus 1 are no more than examples, and example embodiments are not limited thereto.

In example embodiments, the drying module 362 may dry the substrate SB. The substrate SB dried through the drying module 362 may be transferred within the factory interface 302.

In example embodiments, the substrate SB may be moved between the substrate cleaning apparatus 1 and the drying module 362 by the substrate handler 366 when cleaned. The substrate handler 366 may include a first robot 368 and a second robot 370.

In example embodiments, the first robot 368 may include grippers 374 and 376. As illustrated, the first robot 368 may include a plurality of grippers 374 and 376. The first robot 368 may transfer the substrate SB between the input module 324 and the substrate cleaning apparatus 1.

In example embodiments, the second robot 370 may include at least one gripper 378. The second robot 370 may transfer the substrate SB between at least one of the plurality of substrate cleaning apparatuses 1 and the drying module 362.

In example embodiments, the numbers of the grippers of the first robot 368 and the second robot 370 are merely examples, and example embodiments are not limited thereto.

In example embodiments, the first robot 368 and the second robot 370 may move laterally along a rail 372. Accordingly, the substrates SB may be moved between the substrate cleaning apparatus 1 and the drying module 362 by the first robot 368 and the second robot 370 of the substrate handler 366.

In example embodiments, the cleaned substrate SB may be transferred to the output module 356 by the substrate handler 366. The substrate SB transferred to the output module 356 may be tilted into horizontal alignment by the interface robot 325. Then, the substrate SB may be returned to one of the plurality of substrate cassettes 318 by the interface robot 325.

In example embodiments, selectively, the substrate SB may be transferred to the measurement system 380 by the interface robot 325 or the substrate handler 366 before being returned to the substrate cassette 318. The substrate SB may be tested in the measurement system 380.

In example embodiments, the loading robot 304 may be positioned close to the factory interface 302 and the polishing module 306. The loading robot 304 may be positioned between the factory interface 302 and the polishing module 306. The loading robot 304 may transfer the substrate SB between the factory interface 302 and the polishing module 306.

In example embodiments, the polishing module 306 may include at least one chemical mechanical polishing (CMP) station. The polishing module 306 may include at least one CMP station 328, 332, and 335 disposed within an environmentally controlled enclosure 388.

For example, the polishing module 306 may include a bulk CMP station 328, a second CMP station 335, and a third CMP station 332.

In example embodiments, in the bulk CMP station 328, bulk removal of conductive materials may be performed through a CMP process. Then, in the second CMP station 335 and the third CMP station 332, a CMP process for residual conductive materials may be conducted.

In example embodiments, the polishing module 306 may also include a carousel 334 disposed at an upper portion of a machine base 340, a transfer station 336, and a plurality of conditioning devices 382.

In example embodiments, the carousel 334 may be positioned in a center on the machine base 340. The carousel 334 may include a plurality of arms 350. Each of the plurality of arms 350 may support a polishing head assembly 352. The carousel 334 may be indexable so that a plurality of polishing head assemblies 352 may be moved between a plurality of CMP stations 328, 332, and 335 and the transfer station 336.

In example embodiments, the transfer station 336 may include an input buffer station 344, an output buffer station 342, a transfer robot 346, and a load cup assembly 348.

In example embodiments, the substrate SB may be conveyed from the factory interface 302 to the input buffer station 344 by the loading robot 304. The substrate SB to be conveyed may be conveyed to be polished within the polishing module 306.

In example embodiments, the substrate SB may be conveyed from the output buffer station 342 to the factory interface 302 by the loading robot 304. The conveyed substrate SB may be the substrate SB polished through a CMP process.

In example embodiments, the transfer robot 346 may be used to move the substrate SB between the buffer stations 342 and 344 and the load cup assembly 348. The transfer robot 346 may include two gripper assemblies. Each of the two gripper assemblies may have pneumatic gripper fingers holding an edge of the substrate SB.

In example embodiments, a manner of holding the substrate SB through the pneumatic gripper fingers is merely an example, and example embodiments are not limited thereto.

In example embodiments, the plurality of conditioning devices 382 may be disposed adjacently to each of the CMP stations 328, 332, and 335 on the machine base 340. The conditioning device 382 may periodically condition materials for planarization positioned within the CMP stations 328, 332, and 335. Accordingly, the results of planarization for the substrate SB may be maintained uniformly.

As described above, the substrate cleaning apparatus 1 according to example embodiments, by finely adjusting the contact pressure that the brush assembly 10 applies to the substrate SB, the contact area, or the contact friction force for each part of the brush assembly 10 through the brush assembly 10 of a segmented-type having magnetism and the position adjustment part 20 in which magnetic force is generated, may advance the efficiency of substrate cleaning and prevent a failure of wafers from occurring in a cleaning process.

Various example embodiments of the present disclosure are described above in detail, but the scope of the present disclosure is not limited thereto. It is apparent to those of ordinary skill in the art to which the present disclosure pertains that various modifications and transformations may be conducted according to the technical spirit of the present disclosure. In addition, the aforementioned example embodiments may be implemented with some elements removed, and each example embodiment may be implemented in combination with each other.

What is claimed is:

1. A substrate cleaning apparatus comprising:
a core including a plurality of segments having magnetism and one or more connectors connecting the plurality of segments to each other, the core being configured to rotate about a rotation axis;
a brush surrounding at least a portion of the core and configured to rotate together with the core; and
an adjustment frame spaced apart from an outer circumferential surface of the brush, the adjustment frame being configured to generate magnetic force to move at least one of the plurality of segments in a direction intersecting with the rotation axis.

2. The substrate cleaning apparatus of claim 1, wherein the adjustment frame includes a holder spaced apart from the core and one or more electromagnets fixed on the holder and configured to generate magnetic force to move the at least one of the plurality of segments.

3. The substrate cleaning apparatus of claim 2, wherein the one or more electromagnets comprise a plurality of electromagnets disposed along a direction parallel with the rotation axis.

4. The substrate cleaning apparatus of claim 3, wherein a number of the plurality of electromagnets corresponds to a number of the plurality of segments, and
wherein each of the plurality of electromagnets faces a corresponding segment in a direction perpendicular to the rotation axis.

5. The substrate cleaning apparatus of claim 3, wherein a number of the plurality of electromagnets is less than a number of the plurality of segments, and
wherein at least one of the plurality of electromagnets faces the one or more connectors in a direction perpendicular to the rotation axis.

6. The substrate cleaning apparatus of claim 3, wherein each electromagnet of the plurality of electromagnets is positioned to correspond to two segments.

7. The substrate cleaning apparatus of claim 1, wherein the core further includes a conduit inside the plurality of segments and the one or more connectors, in which a cleaning liquid is configured to flow, and
wherein at least one segment among the plurality of segments includes:
a magnetic material having magnetism; and
a spray hole in fluid communication with the conduit, through which the cleaning liquid is configured to be sprayed.

8. The substrate cleaning apparatus of claim 7, wherein the at least one segment among the plurality of segments further includes a nonmagnetic material combined with the magnetic material.

9. The substrate cleaning apparatus of claim 7, wherein the magnetic material includes a magnetic polymer or a magnetic particle,
wherein the magnetic polymer includes PANiCNQ polymer, and
wherein the magnetic particle is a metal particle including any one or more selected from a group having iron (Fe), chromium (Cr), nickel (Ni), cobalt (Co), and manganese (Mn).

10. The substrate cleaning apparatus of claim 1, wherein the plurality of segments includes a first segment and a second segment having lengths different from each other in a direction of the rotation axis.

11. The substrate cleaning apparatus of claim 1, wherein the plurality of segments and the one or more connectors are disposed alternately along the rotation axis, and
wherein the one or more connectors are deformable in response to a movement of at least one of the plurality of segments.

12. The substrate cleaning apparatus of claim 11, wherein the one or more connectors include a corrugated pipe or a braided wire.

13. The substrate cleaning apparatus of claim 1, wherein the brush includes a plurality of brush segments, each brush segment of the plurality of brush segments corresponding to a respective segment of the plurality of segments.

14. A substrate cleaning apparatus comprising:
a core including a plurality of segments, the plurality of segments being configured to spray a cleaning liquid for cleaning a semiconductor substrate, and one or more connectors connecting the plurality of segments to each other; and
a brush surrounding at least a portion of the core and configured to rotate together with the core as the core rotates about a rotation axis,
wherein at least one segment among the plurality of segments is configured to move in a direction intersecting the rotation axis with respect to another segment, and
wherein a connector of the one or more connectors that is connected to the at least one segment is configured to change shape with movement of the at least one segment.

15. The substrate cleaning apparatus of claim 14, wherein at least one segment among the plurality of segments includes a magnetic material having magnetism, and
wherein one or more magnetic objects, in which a magnetic force for moving the magnetic material in the direction intersecting the rotation axis is generated, are disposed at one side of the core.

16. The substrate cleaning apparatus of claim 15, wherein the one or more magnetic objects comprise a plurality of magnetic objects arranged in a direction parallel with the rotation axis.

17. The substrate cleaning apparatus of claim 15, wherein the magnetic material includes a magnetic polymer or a magnetic particle, and
wherein the one or more magnetic objects are electromagnets.

18. A substrate cleaning apparatus comprising:
a core including a plurality of segments arranged in a longitudinal direction of the core, the core being configured to rotate about a rotational axis;
a brush surrounding at least a portion of the core and configured to rotate together with the core; and
a controller configured to rotate the core and configured to move at least one of the plurality of segments in a radial direction of the core.

19. The substrate cleaning apparatus of claim 18, wherein each segment of the plurality of segments includes a magnetic material.

20. The substrate cleaning apparatus of claim 19, further comprising an adjustment frame including a plurality of electromagnets arranged in the longitudinal direction,
wherein the controller is configured to move the at least one of the plurality of segments by applying a current to a corresponding electromagnet of the plurality of electromagnets.
